(19) United States
(12) Patent Application Publication
(10) Pub. No.: US 2026/0351180 A1
(43) Pub. Date: Nov. 5, 2026

(54) DISPLAY PANEL, DRIVING METHOD THEREOF AND DISPLAY DEVICE

(71) Applicant: Xiamen Tianma Microelectronics Co., Ltd., Xiamen (CN)

(72) Inventors: Qingjun LAI, Xiamen (CN); Xingyao ZHOU, Xiamen (CN); Zhiqiang XIA, Xiamen (CN)

(73) Assignee: Xiamen Tianma Microelectronics Co., Ltd., Xiamen (CN)

(21) Appl. No.: 19/718,160

(22) Filed: Jun. 24, 2026

(30) Foreign Application Priority Data
Feb. 27, 2026 (CN) 202610236334.1

(51) Int. Cl. G09G 3/3233; G11C 19/28

(52) U.S. Cl. CPC G09G 3/3233; G11C 19/28; G09G 2300/0842; G09G 2300/0861; G09G 2310/0286; G09G 2310/08

(57) ABSTRACT

Provided is a display panel. In its shift register unit, an input module is connected to a first input terminal and a first node, and connected to a second input terminal and a second node based on a signal of a clock signal terminal; a first inverter is coupled between the first node and the second node; a second inverter is coupled oppositely therebetween; a first cascade output module is connected to a first fixed potential signal terminal and a first cascade output terminal based on a signal of the first node; a second cascade output module is connected to a second fixed potential signal terminal and a second cascade output terminal based on a signal of the second node. An output terminal of the shift register unit is connected to the first node.

### CROSS-REFERENCE TO RELATED APPLICATION

This application claims priority to Chinese Patent Application No. 202610236334.1, filed on Feb. 27, 2026, which is hereby incorporated by reference in its entirety.

### TECHNICAL FIELD

The present disclosure relates to the field of display technologies, and in particular, to a display panel, a driving method thereof, and a display device.

### BACKGROUND

To control subpixels in a display panel, it is necessary to provide a shift register circuit in the display panel that provides control signals to the subpixels. At present, the shift register circuit has a relatively complex structure and needs to occupy a large space in the display panel, which limits the narrow bezel design of the display panel. In addition, the potential of some nodes in the shift register circuit is not stable enough, which affects the circuit stability.

### SUMMARY

In view of this, embodiments of the present disclosure provide a display panel, a driving method thereof, and a display device, to simplify a structure of a shift register circuit in the display panel and improve circuit stability.

In a first aspect, an embodiment of the present disclosure provides a display panel, including a plurality of subpixels and a shift register circuit, where the shift register circuit includes a plurality of cascaded shift register units, and the shift register units are electrically connected to the subpixels. The shift register unit includes: an input module electrically connected to a first input terminal and a first node, and electrically connected to a second input terminal and a second node, in response to a signal output by a clock signal terminal; a first inverter and a second inverter, where an input terminal of the first inverter is electrically connected to the first node, and an output terminal of the first inverter is electrically connected to the second node; and an input terminal of the second inverter is electrically connected to the second node, and an output terminal of the second inverter is electrically connected to the first node; a first cascade output module electrically connected to a first fixed potential signal terminal and a first cascade output terminal in response to a signal of the first node; and a second cascade output module electrically connected to a second fixed potential signal terminal and a second cascade output terminal in response to a signal of the second node. An output terminal of the shift register unit is electrically connected to the first node.

In a second aspect, an embodiment of the present disclosure provides a display device including a display panel. The display panel includes a plurality of subpixels and a shift register circuit, where the shift register circuit includes a plurality of cascaded shift register units, and the shift register units are electrically connected to the subpixels. The shift register unit includes: an input module electrically connected to a first input terminal and a first node, and electrically connected to a second input terminal and a second node, in response to a signal output by a clock signal terminal; a first inverter and a second inverter, where an input terminal of the first inverter is electrically connected to the first node, and an output terminal of the first inverter is electrically connected to the second node; and an input terminal of the second inverter is electrically connected to the second node, and an output terminal of the second inverter is electrically connected to the first node; a first cascade output module electrically connected to a first fixed potential signal terminal and a first cascade output terminal in response to a signal of the first node; and a second cascade output module electrically connected to a second fixed potential signal terminal and a second cascade output terminal in response to a signal of the second node. An output terminal of the shift register unit is electrically connected to the first node.

In a third aspect, an embodiment of the present disclosure provides a driving method of a display panel, where the display panel includes a shift register circuit, and the shift register circuit includes a plurality of cascaded shift register units. The shift register unit includes: an input module electrically connected to a first input terminal and a first node, and electrically connected to a second input terminal and a second node, in response to a signal output by a clock signal terminal; a first inverter and a second inverter, where an input terminal of the first inverter is electrically connected to the first node, and an output terminal of the first inverter is electrically connected to the second node; and an input terminal of the second inverter is electrically connected to the second node, and an output terminal of the second inverter is electrically connected to the first node; a first cascade output module electrically connected to a first fixed potential signal terminal and a first cascade output terminal in response to a signal of the first node; and a second cascade output module electrically connected to a second fixed potential signal terminal and a second cascade output terminal in response to a signal of the second node. An output terminal of the shift register unit is electrically connected to the first node. an operating cycle of the shift register unit includes a first phase and a second phase, and the driving method includes: in the first phase, providing, by the input module, an enable level to the first node and a disable level to the second node in response to the signal output by the clock signal terminal, where the enable level is used to control the first cascade output module to be turned on, and the disable level is used to control the second cascade output module to be turned off; providing, by the first cascade output module, the disable level to the first cascade output terminal in response to the signal of the first node; and providing, by the second cascade output module, the enable level to the second cascade output terminal in response to the signal of the second node; and in the second phase, providing, by the input module, the disable level to the first node and the enable level to the second node in response to the signal output by the clock signal terminal; providing, by the first cascade output module, the enable level to the first cascade output terminal in response to the signal of the first node; and providing, by the second cascade output module, the disable level to the second cascade output terminal in response to the signal of the second node.

### BRIEF DESCRIPTION OF DRAWINGS

In order to more clearly describe the technical solutions of the embodiments of the present disclosure, the accompanying drawings used in the embodiments will be briefly described below, obviously, the drawings described below are only some embodiments of the present disclosure, and for those skilled in the art, other drawings may be obtained according to these drawings.

FIG. 1 is a schematic diagram of a display panel according to an embodiment of the present disclosure;

FIG. 2 is a circuit schematic diagram of a shift register unit according to an embodiment of the present disclosure;

FIG. 3 is a schematic diagram of an operating timing of a shift register unit according to an embodiment of the present disclosure;

FIG. 4 is a schematic diagram of a shift register circuit according to an embodiment of the present disclosure;

FIG. 5 is a schematic diagram of an equivalent circuit of two adjacent stages of shift register units in FIG. 4;

FIG. 6 is a circuit schematic diagram of another shift register unit according to an embodiment of the present disclosure;

FIG. 7 is a schematic diagram of another shift register unit according to an embodiment of the present disclosure;

FIG. 8 is a schematic diagram of an equivalent circuit of a subpixel according to an embodiment of the present disclosure;

FIG. 9 is a schematic diagram of an operating timing of a subpixel according to an embodiment of the present disclosure; and

FIG. 10 is a structural schematic diagram of a display device according to an embodiment of the present disclosure.

### DESCRIPTION OF EMBODIMENTS

In order to better understand the technical solutions of the present disclosure, embodiments of the present disclosure will be described in detail below with reference to the accompanying drawings.

It should be clear that the described embodiments are only some of the embodiments of the present disclosure, rather than all of the embodiments. Based on the embodiments of the present disclosure, all other embodiments obtained by those of ordinary skill in the art shall fall within the protection scope of the present disclosure.

The terms used in the embodiments of the present disclosure are merely for the purpose of describing specific embodiments, but not intended to limit the present disclosure. Singular forms of “a/an”, “said” and “the” used in the embodiments of the present disclosure and the appended claims are also intended to include a plural form, unless the context clearly indicates other meaning otherwise.

It should be understood that the term “and/or” used in the context represents an association relationship to describe associated objects, and can indicate three relationships, for example, A and/or B can indicate A alone, A and B, and B alone. In addition, the symbol “/” in the context generally indicates that the relationship between the objects in front and at the back of “/” is an “or” relationship.

It should be understood that although the terms “first”, “second” and “third” can be used in the embodiments of the present disclosure to describe transistors, these transistors should not be limited to these terms. These terms are used only to distinguish the transistors from each other. For example, without departing from the scope of the embodiments of the present disclosure, a first transistor can also be referred to as a second transistor, similarly, a second transistor can also be referred to as a first transistor.

An embodiment of the present disclosure provides a display panel, as shown in FIG. 1, which is a schematic diagram of a display panel according to an embodiment of the present disclosure, the display panel includes a shift register circuit 2 and a plurality of subpixels 1. The shift register circuit 2 includes a plurality of cascaded shift register units 20. The shift register units 20 are electrically connected to the subpixels 1 for controlling whether the subpixels 1 are turned on or not.

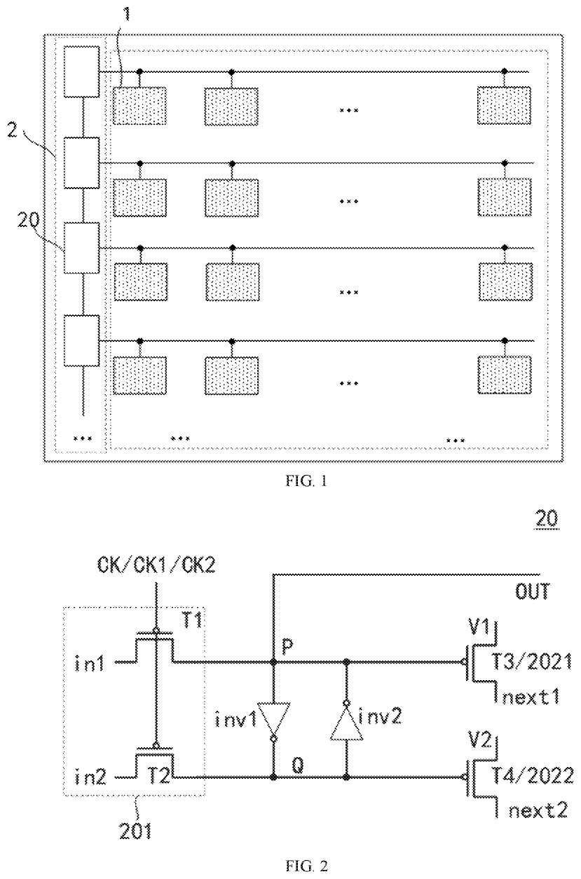

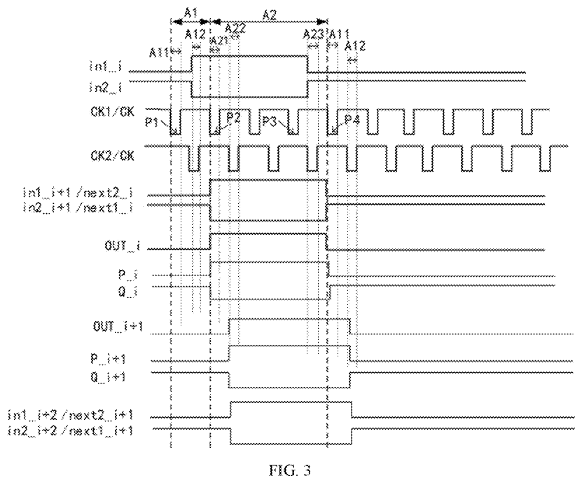

Exemplarily, as shown in FIG. 2, which is a circuit schematic diagram of a shift register unit according to an embodiment of the present disclosure, the shift register unit 20 includes an input module 201, a first inverter inv1, a second inverter inv2, a first cascade output module 2021 and a second cascade output module 2022.

The input module 201, in response to a signal output by a clock signal terminal CK, is electrically connected to a first input terminal in1 and a first node P, and electrically connected to a second input terminal in2 and a second node Q. Exemplarily, when the shift register unit 20 is in operation, signals of the first node P and the second node Q can be configured as inverted signals through a signal input to the first input terminal in1 and a signal input to the second input terminal in2.

As shown in FIG. 2, an input terminal of the first inverter inv1 is electrically connected to the first node P, and an output terminal of the first inverter inv1 is electrically connected to the second node Q; an input terminal of the second inverter inv2 is electrically connected to the second node Q, and an output terminal of the second inverter inv2 is electrically connected to the first node P. That is, the first inverter inv1 and the second inverter inv2 are connected end to end. With this configuration, potentials of the first node P and the second node Q can be latched by using the first inverter inv1 and the second inverter inv2, which is beneficial to improving the potential stability of the first node P and the second node Q.

With continued reference to FIG. 2, the first cascade output module 2021 is configured to be electrically connected a first fixed potential signal terminal V1 and a first cascade output terminal next1 in response to the signal of the first node P; and the second cascade output module 2022 is configured to be electrically connected a second fixed potential signal terminal V2 and a second cascade output terminal next2 in response to the signal of the second node Q. The first cascade output terminal next1 and the second cascade output terminal next2 may be electrically connected to a next-stage shift register unit 20 in the shift register circuit 2.

Exemplarily, both the first fixed potential signal terminal V1 and the second fixed potential signal terminal V2 may be configured to provide a constant signal.

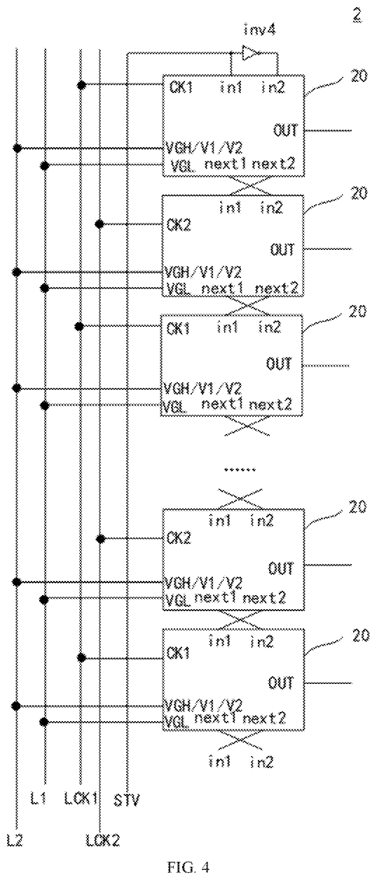

The first fixed potential signal terminal V1 is configured to provide a disable level to the first cascade output terminal next1 when the first node P is at an enable level, and the disable level can control the second cascade output module 2022 to be turned off. For the shift register unit 20, as shown in FIG. 2, the signal input to the second input terminal in2 determines the turn-on or turn-off of the second cascade output module 2022 in the current-stage shift register unit 20. When designing the shift register circuit 2, exemplarily, with reference to FIG. 4 and FIG. 5, in two adjacent stages of shift register units 20, the first cascade output terminal next1 of a previous-stage shift register unit 20 may be electrically connected to the second input terminal in2 of a next-stage shift register unit 20. Based on this configuration, the signal provided by the first fixed potential signal terminal V1 electrically connected to the previous-stage shift register unit 20 may be written into the second input terminal in2 of the next-stage shift register unit 20, thereby controlling the turn-on or turn-off of the second cascade output module 2022 of the next-stage shift register unit 20.

The second fixed potential signal terminal V2 is configured to provide a disable level to the second cascade output terminal next2 when the second node Q is at the enable level, and the disable level can control the first cascade output module 2021 to be turned off. For the shift register unit 20, as shown in FIG. 2, the signal input to the first input terminal in1 determines the turn-on or turn-off of the first cascade output module 2021 in the current-stage shift register unit 20. When designing the shift register circuit 2, exemplarily, with reference to FIG. 4 and FIG. 5, in two adjacent stages of shift register units 20, the second cascade output terminal next2 of a previous-stage shift register unit 20 may be electrically connected to the first input terminal in1 of a next-stage shift register unit 20. Based on this configuration, the signal provided by the second fixed potential signal terminal V2 electrically connected to the previous-stage shift register unit 20 may be written into the first input terminal in1 of the next-stage shift register unit 20, thereby controlling the turn-on or turn-off of the first cascade output module 2021 of the next-stage shift register unit 20.

Optionally, in some embodiments, the signals provided by the first fixed potential signal terminal V1 and the second fixed potential signal terminal V2 may be the same type. For example, both provide a constant high-level signal. Exemplarily, the first cascade output module 2021 and the second cascade output module 2022 may include transistors having the same channel type, for example, both may include P-type transistors.

Optionally, in some embodiments, the first fixed potential signal terminal V1 and the second fixed potential signal terminal V2 may be electrically connected to each other, so that the two terminals receive the same signal.

As shown in FIG. 2, an output terminal OUT of the shift register unit 20 is electrically connected to the first node P. With this configuration, a logic potential of the output terminal OUT of the shift register unit 20 may be the same as a logic potential of the first node P. For example, when the logic potential of the first node P is at a low level, the logic potential of the output terminal OUT is also at a low level; when the logic potential of the first node P is at a high level, the logic potential of the output terminal OUT is also at a high level.

In some embodiments, the output terminal OUT of the shift register unit 20 is electrically connected to the subpixel 1, and a signal output by the output terminal OUT is used to drive the subpixel 1 shown in FIG. 1 to operate.

When the shift register unit 20 is in operation, with reference to FIG. 2 and FIG. 3, where FIG. 3 is a schematic diagram of an operating timing of a shift register unit according to an embodiment of the present disclosure, the operating process of the shift register unit includes a first phase A1 and a second phase A2.

During at least part of the period in the first phase A1, the aforementioned input module 201, in response to the signal output by the clock signal terminal CK, provides an enable level to the first node P by using the first input terminal in1, and provides a disable level to the second node Q by using the second input terminal in2, where the enable level is used to control the first cascade output module 2021 to be turned on, and the disable level is used to control the second cascade output module 2022 to be turned off. For example, when both the first cascade output module 2021 and the second cascade output module 2022 include P-type transistors, the enable level is a low level, and the disable level is a high level.

The first cascade output module 2021, in response to the signal of the first node P, provides a disable level to the first cascade output terminal next1 by using the signal of the first fixed potential signal terminal V1. The disable level may control the second cascade output module 2022 of the next-stage shift register unit 20 to be turned off. Exemplarily, when the second cascade output module 2022 includes a P-type transistor, the disable level is a high level.

The second cascade output module 2022 is turned off in response to the signal of the second node Q, and the second fixed potential signal terminal V2 stops providing the disable level to the second cascade output terminal next2, where the disable level may control the first cascade output module 2021 of the next-stage shift register unit 20 to be turned off. Exemplarily, when the first cascade output module 2021 includes a P-type transistor, the disable level is a high level.

Exemplarily, in the first phase A1, the second cascade output terminal next2 may output an enable level, and the enable level may control the first cascade output module 2021 of the next-stage shift register unit 20 to be turned on. For example, when the first cascade output module 2021 includes a P-type transistor, as shown in FIG. 3, the enable level includes a low level. Exemplarily, a low-level signal of the first cascade output module 2021 of any shift register unit 20 may be obtained through the feedback from the next-stage shift register unit 20 that is electrically connected to the current-stage shift register unit 20.

During at least part of the period in the first phase A1, the potential of the output terminal OUT is at an enable level, and the enable level can control the subpixel 1 to be turned on.

With continued reference to FIG. 3, during at least part of the period in the second phase A2, the input module 201, in response to the signal output by the clock signal terminal CK, provides a disable level to the first node P by using the first input terminal in1, and provides an enable level to the second node Q by using the second input terminal in2; and the first cascade output module 2021, in response to the signal of the first node P, stops providing a disable level to the first cascade output terminal next1. In some embodiments, the first cascade output terminal next1 may receive an enable level at this phase. Optionally, the enable level may be obtained through feedback from the next-stage shift register unit 20.

During at least part of the period in the second phase A2, the second cascade output module 2022, in response to the signal of the second node Q, provides a disable level to the second cascade output terminal next2 by using the second fixed potential signal terminal V2.

In some embodiments, in the second phase A2, the first cascade output terminal next1 may output an enable level, and the enable level may control the second cascade output module 2022 of the next-stage shift register unit 20 to be turned on. For example, when the second cascade output module 2022 includes a P-type transistor, the enable level includes a low level shown in FIG. 3. Optionally, the low-level signal of the first cascade output terminal next1 of any shift register unit 20 may be obtained through feedback from the next-stage shift register unit 20 that is electrically connected to the current-stage shift register unit 20.

During at least part of the period in the second phase A2, the potential of the output terminal OUT is a disable level, and the disable level can control the subpixel 1 not to be turned on.

With the display panel according to the embodiments of the present disclosure, by configuring the shift register unit 20 to include the input module 201, the first inverter inv1, the second inverter inv2, the first cascade output module 2021 and the second cascade output module 2022, the output signal of the output terminal OUT of the shift register unit 20 can be shifted relative to the signal input to the first input terminal in1, thereby realizing the shifting function of the shift register unit 20.

Moreover, in the embodiments of the present disclosure, by providing the first inverter inv1 and the second inverter inv2, the potential stability of the first node P and the second node Q can be improved, the potential of the first node P or the second node Q is prevented from being in a floating state, thereby improving the stability of the signal written into the internal node of the shift register unit 20. In addition, with this configuration, there is no need to provide a capacitor for stabilizing the potential of the first node P or the second node Q in the shift register unit 20, thereby simplifying the circuit structure of the shift register unit while ensuring signal stability.

Exemplarily, as shown in FIG. 3, the signal input to the first input terminal in1 and the signal input to the second input terminal in2 are mutually inverted signals. That is, when one of them is at a low level, the other is at a high level. In the embodiments of the present disclosure, by configuring the above signals to be mutually inverted signals, the first node P and the second node Q may be written with signals with opposite phases through the first input terminal in1 and the second input terminal in2, respectively.

Exemplarily, as shown in FIG. 3, the signal output by the clock signal terminal CK includes a plurality of active pulses, where the active pulses can control the input module 201 to be turned on. For example, when the input module 201 includes a P-type transistor, the active pulse includes a low-level pulse.

As shown in FIG. 3, in some embodiments, a rising edge of the signal input to the first input terminal in1 and a falling edge of the signal input to the second input terminal in2 are both located between two adjacent active pulses of the signal output by the clock signal terminal CK.

Taking, as an example, a case where the rising edge of the signal input to the first input terminal in1 and the falling edge of the signal input to the second input terminal in2 are both located between the adjacent first active pulse P1 and second active pulse P2 output by the clock signal terminal CK, with this configuration, it can be ensured that when the clock signal terminal CK outputs the first active pulse P1, the signal input to the first input terminal in1 is at a low level, and the low level may pull the first node P low through the turned-on input module 201; and the signal input to the second input terminal in2 is at a high level, and the high level may pull the second node Q high through the turned-on input module 201.

The first node P having a low level may control the first cascade output module 2021 to be turned on, so that a disable level provided by the first fixed potential signal terminal V1, such as a high level, may pull the first cascade output terminal next1 high through the first cascade output module 2021.

The second node Q having a high level may control the second cascade output module 2022 to be turned off, so that a disable level provided by the second fixed potential signal terminal V2, such as a high level, may be prevented from pulling the second cascade output terminal next2 high through the second cascade output module 2022.

When the clock signal terminal CK outputs the second active pulse P2, the signal input to the first input terminal in1 has been switched to a high level, and the signal input to the second input terminal in2 has been switched to a low level. The high-level signal input to the first input terminal in1 may be written into the first node P through the turned-on input module 201, and the first node P controls the first cascade output module 2021 to be turned off, thereby stopping the disable level provided by the first fixed potential signal terminal V1, such as a high level, from being written into the first cascade output terminal next1. The low-level signal input to the second input terminal in2 may be written into the second node Q through the turned-on input module 201, and the second node Q controls the second cascade output module 2022 to be turned on, thereby enabling the disable level provided by the second fixed potential signal terminal V2, such as a high level, to pull the second cascade output terminal next2 high through the second cascade output module 2022.

Optionally, as shown in FIG. 3, the falling edge of the signal input to the first input terminal in1 and the rising edge of the signal input to the second input terminal in2 are both located between another two adjacent active pulses of the clock signal terminal CK.

Taking, as an example, a case where the falling edge of the signal input to the first input terminal in1 and the rising edge of the signal input to the second input terminal in2 are both located between a third active pulse P3 and a fourth active pulse P4 of the clock signal terminal CK shown in FIG. 3, with this configuration, for any shift register unit 20, it can be ensured that when the clock signal terminal CK electrically connected to the shift register unit 20 outputs the third active pulse P3, the first input terminal in1 may still continue inputting a high-level signal, so that the high-level signal may be written into the first node P through the turned-on input module 201, thereby controlling the first cascade output module 2021 to be turned off, and avoiding the first cascade output terminal next1 from outputting a high level.

When the clock signal terminal CK electrically connected to the shift register unit 20 outputs the third active pulse P3, the second input terminal in2 may still continue inputting a low-level signal, so that the low-level signal may be written into the second node Q through the turned-on input module 201, thereby controlling the second cascade output module 2022 to be turned on, and enabling the disable level signal provided by the second fixed potential signal terminal V2, such as a high-level signal, to be written into the second cascade output terminal next2 through the turned-on second cascade output module 2022.

When the clock signal terminal CK electrically connected to the shift register unit 20 outputs the fourth active pulse P4, the signal input to the first input terminal in1 may be switched to a low-level signal, so that the low-level signal may be written into the first node P through the turned-on input module 201, thereby controlling the first cascade output module 2021 to be turned on, and enabling the disable level signal provided by the first fixed potential signal terminal V1, such as a high-level signal, to be written into the first cascade output terminal next1 through the turned-on first cascade output module 2021.

When the clock signal terminal CK electrically connected to the shift register unit 20 outputs the fourth active pulse P4, the signal input to the second input terminal in2 may be switched to a high-level signal, so that the high-level signal may be written into the second node Q through the turned-on input module 201, thereby controlling the second cascade output module 2022 to be turned off, and avoiding the disable level signal provided by the second fixed potential signal terminal V2, such as a high-level signal, from being written into the second cascade output terminal next2.

Exemplarily, as shown in FIG. 2, the input module 201 includes a first input transistor T1 and a second input transistor T2, a first electrode of the first input transistor T1 is electrically connected to the first input terminal in1, a second electrode of the first input transistor T1 is electrically connected to the first node P, a first electrode of the second input transistor T2 is electrically connected to the second input terminal in2, and a second electrode of the second input transistor T2 is electrically connected to the second node Q. A gate of the first input transistor T1 is electrically connected to a gate of the second input transistor T2, and both are electrically connected to the clock signal terminal CK.

In some embodiments, channel types of the first input transistor T1 and the second input transistor T2 may be the same. FIG. 2 illustrates the case where both transistors are P-type transistors. The two transistors are both controlled by the same signal and can be turned on or off simultaneously. With this configuration, in combination with the configuration that the signal provided by the first input terminal in1 and the signal provided by the second input terminal in2 are inverted signals with respect to each other, when one of the first input transistor T1 and the second input transistor T2 transmits a low-level signal and incurs a loss, the other can transmit a high-level signal, which is beneficial for reducing loss during signal transmission and improving the potential accuracy of the first node P and the second node Q.

For example, when the signal output by the clock signal terminal CK is at a low level and the signal input to the first input terminal in1 is at a low level, if only the first input transistor T1 including a P-type transistor is provided, it will incur a threshold loss during transmission. In the embodiments of the present disclosure, by providing the second input transistor T2 electrically connected to the second input terminal in2, and by causing the second input terminal in2 to transmit a high level, the loss of the second input transistor T2 during signal transmission can be reduced, thereby improving the accuracy of the high level at the second node Q, and reducing the potential loss at the first node P through the action of the second inverter inv2.

Exemplarily, as shown in FIG. 4 and FIG. 5, where FIG. 4 is a schematic diagram of a shift register circuit according to an embodiment of the present disclosure, FIG. 5 is a schematic diagram of an equivalent circuit of two adjacent stages of shift register units 20 in FIG. 4, the clock signal terminal CK includes a first clock signal terminal CK1 and a second clock signal terminal CK2. In two adjacent stages of shift register units 20, the input module 201 of one-stage shift register unit 20 is responsive to the signal output by the first clock signal terminal CK1; and the input module 201 of the other-stage shift register unit 20 is responsive to the signal output by the second clock signal terminal CK2. In two adjacent stages of shift register units 20, the second cascade output terminal next2 of the previous-stage shift register unit 20 is electrically connected to the first input terminal in1 of the next-stage shift register unit 20, and the first cascade output terminal next1 of the previous-stage shift register unit 20 is electrically connected to the second input terminal in2 of the next-stage shift register unit 20.

With this configuration, the signals output by the second cascade output terminal next2 and the first cascade output terminal next1 of the current-stage shift register unit 20 may be used to respectively provide signals to the first input terminal in1 and the second input terminal in2 of the next-stage shift register unit 20, without needing to additionally provide signals to the first input terminal in1 and the second input terminal in2 of the shift register unit 20 of each stage except the first stage, which is beneficial for simplifying circuit arrangement.

In some embodiments, the signals output by the first clock signal terminal CK1 and the second clock signal terminal CK2 are both pulse signals. Exemplarily, the periods of the two signals may be the same.

Exemplarily, as shown in FIG. 3, when the signal output by the first clock signal terminal CK1 is an enable level, the signal output by the second clock signal terminal CK2 is a disable level; and when the signal output by the second clock signal terminal CK2 is an enable level, the signal output by the first clock signal terminal CK1 is a disable level.

Exemplarily, as shown in FIG. 2 and FIG. 5, the first cascade output module 2021 includes a first output transistor T3, the second cascade output module 2022 includes a second output transistor T4, a first electrode of the first output transistor T3 is electrically connected to the first fixed potential signal terminal V1, a second electrode of the first output transistor T3 is electrically connected to the first cascade output terminal next1, and a gate of the first output transistor T3 is electrically connected to the first node P; a first electrode of the second output transistor T4 is electrically connected to the second fixed potential signal terminal V2, a second electrode of the second output transistor T4 is electrically connected to the second cascade output terminal next2, and a gate of the second output transistor T4 is electrically connected to the second node Q.

In some embodiments, the first output transistor T3 and the second output transistor T4 have the same channel type.

Under the control of the first node P and the second node Q, whose signals are inverted with respect to each other, the first output transistor T3 and the second output transistor T4 can be turned on in a time-division manner.

Optionally, both the first output transistor T3 and the second output transistor T4 are P-type transistors. With this configuration, the driving capability of the first output transistor T3 and the second output transistor T4 can be improved, and thereby improving the driving capability of the output signals of the first cascade output terminal next1 and the second cascade output terminal next2 which are electrically connected to the first output transistor T3 and the second output transistor T4.

Exemplarily, as shown in FIG. 3, the signal output by the first cascade output terminal next1 and the signal output by the second cascade output terminal next2 have opposite phases.

With this configuration, for two adjacent stages of shift register units 20, such as for the i-th-stage shift register unit 20 and the (i+1)-th-stage shift register unit 20 shown in FIG. 4, the signal output by the first cascade output terminal next1 of the i-th-stage shift register unit 20 may serve as the signal input to the second input terminal in2 of the (i+1)-th-shift register unit 20, and the signal output by the second cascade output terminal next2 of the i-th-stage shift register unit 20 may serve as the signal input to the first input terminal in1 of the (i+1)-th-shift register unit 20.

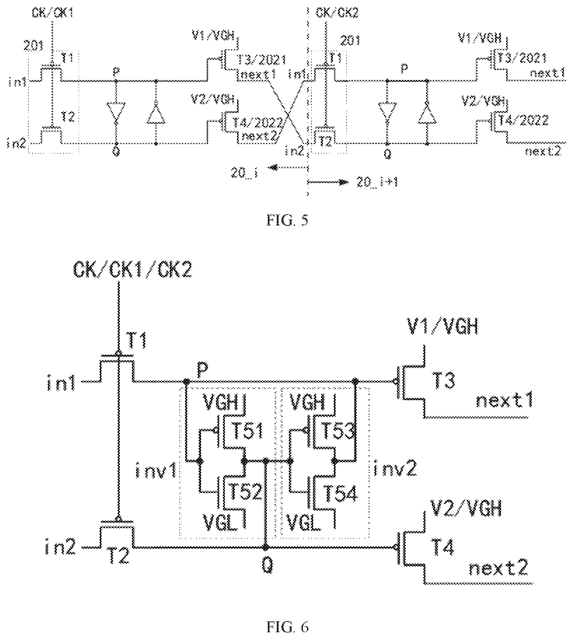

Optionally, as shown in FIG. 6, which is a circuit schematic diagram of another shift register unit according to an embodiment of the present disclosure, the first inverter inv1 includes a first transistor T51 and a second transistor T52 having different channel types, a first electrode of the first transistor T51 is electrically connected to a first potential signal terminal VGH, a second electrode of the first transistor T51 is electrically connected to the second node Q, and a gate of the first transistor T51 is electrically connected to the first node P; a first electrode of the second transistor T52 is electrically connected to a second potential signal terminal VGL, a second electrode of the second transistor T52 is electrically connected to the second node Q, and a gate of the second transistor T52 is electrically connected to the first node P.

The second inverter inv2 includes a third transistor T53 and a fourth transistor T54 having different channel types, a first electrode of the third transistor T53 is electrically connected to the first potential signal terminal VGH, a second electrode of the third transistor T53 is electrically connected to the first node P, and a gate of the third transistor T53 is electrically connected to the second node Q; a first electrode of the fourth transistor T54 is electrically connected to the second potential signal terminal VGL, a second electrode of the fourth transistor T54 is electrically connected to the first node P, and a gate of the fourth transistor T54 is electrically connected to the second node Q. The potential of the second potential signal terminal VGL is lower than the potential of the first potential signal terminal VGH.

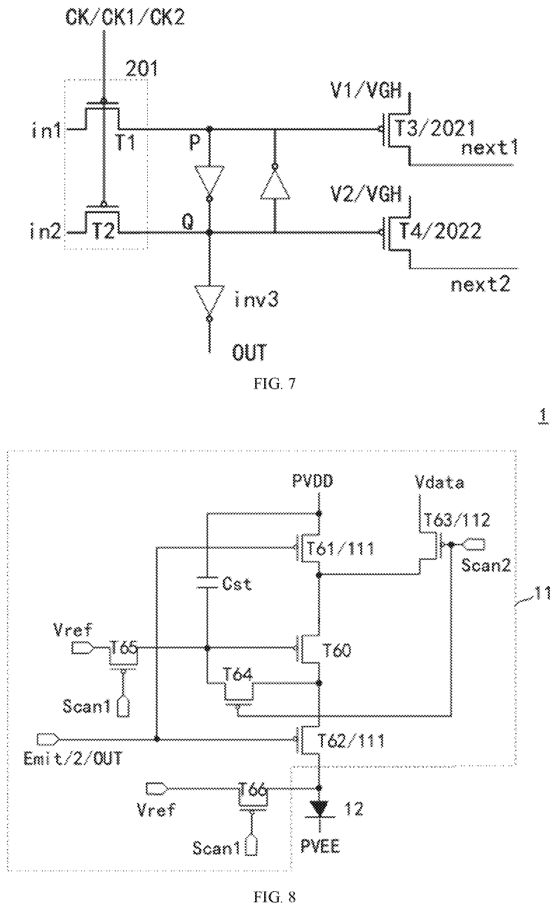

Exemplarily, as shown in FIG. 7, which is a schematic diagram of another shift register unit according to an embodiment of the present disclosure, the shift register unit 20 further includes a third inverter inv3, an input terminal of the third inverter inv3 is electrically connected to the second node Q, and an output terminal of the third inverter inv3 is electrically connected to the output terminal OUT of the shift register unit 20. That is, the logic potential of the output terminal OUT of the shift register unit 20 is the same as that of the first node P. The provision of the third inverter inv3 is beneficial for increasing the driving capability of the output signal of the output terminal OUT of the shift register unit 20.

Exemplarily, as shown in FIG. 4, the shift register circuit 2 further includes a starting signal line STV and a fourth inverter inv4, and in the first-stage shift register unit 20, one of the first input terminal in1 and the second input terminal in2 is electrically connected to the starting signal line STV and an input terminal of the fourth inverter inv4, and the other is electrically connected to an output terminal of the fourth inverter inv4. FIG. 4 illustrates that the first input terminal in1 is electrically connected to the starting signal line STV, and the second input terminal in2 is electrically connected to the output terminal of the fourth inverter inv4. With this configuration, there is no need to provide a separate signal line for each of the first input terminal in1 and the second input terminal in2, which can simplify the wiring arrangement of the display panel.

Optionally, as shown in FIG. 4, the shift register circuit 2 further includes a first clock signal line LCK1, a second clock signal line LCK2, a first level signal line L1 and a second level signal line L2. The first clock signal line LCK1 is electrically connected to the first clock signal terminal CK1 of the shift register unit 20, and the second clock signal line LCK2 is electrically connected to the second clock signal terminal CK2 of the shift register unit 20. The first level signal line L1 is electrically connected to the first fixed potential signal terminal V1 and the second fixed potential signal terminal V2 of the shift register unit 20. The second level signal line L2 is electrically connected to the second potential signal terminal VGL of the shift register unit 20.

Exemplarily, as shown in FIG. 8, which is a schematic diagram of an equivalent circuit of a subpixel according to an embodiment of the present disclosure, the subpixel 1 includes a pixel driving circuit 11 and a light-emitting element 12 that are electrically connected, and the pixel driving circuit 11 provides a driving current to the light-emitting element 12.

Optionally, the light emitting element 12 includes any one of an organic light emitting diode (OLED), a micro light emitting diode (Micro-LED), and a quantum dot light emitting diode (QLED), which is not limited in the embodiments of the present disclosure.

As shown in FIG. 8, the pixel driving circuit 11 includes a light-emitting control module 111, and the aforementioned shift register circuit 2 is electrically connected to the light-emitting control module 111. Exemplarily, the shift register circuit 2 is electrically connected to the control terminal of the light-emitting control module 111.

Exemplarily, as shown in FIG. 8, the light-emitting control module 111 includes a first light-emitting control transistor T61 and a second light-emitting control transistor T62, and the shift register circuit 2 is electrically connected to gates of the first light-emitting control transistor T61 and the second light-emitting control transistor T62.

As shown in FIG. 8, the display panel includes a light-emitting control signal line Emit, which is electrically connected to the gates of the first light-emitting control transistor T61 and the second light-emitting control transistor T62. The output terminal OUT of the aforementioned shift register circuit 2 is electrically connected to the light-emitting control signal line Emit.

Optionally, as shown in FIG. 8, the pixel driving circuit 11 further includes a driving transistor T60, a data writing transistor T63, a threshold compensation transistor T64, a first reset transistor T65, a second reset transistor T66 and a storage capacitor Cst.

A first electrode of the aforementioned first light-emitting control transistor T61 is electrically connected to a first power supply voltage terminal PVDD, and a second electrode of the first light-emitting control transistor T61 is electrically connected to a first electrode of the driving transistor T60. A gate of the data writing transistor T63 and a gate of the threshold compensation transistor T64 are both electrically connected to a second scan line Scan2, a first electrode of the data writing transistor T63 is electrically connected to a data line Vdata, and a second electrode of the data writing transistor T63 is electrically connected to the first electrode of the driving transistor T60. A first electrode of the threshold compensation transistor T64 is electrically connected to a second electrode of the driving transistor T60, and a second electrode of the threshold compensation transistor T64 is electrically connected to a gate of the driving transistor T60. A gate of the first reset transistor T65 and a gate of the second reset transistor T66 are both electrically connected to a first scan line Scan1, a first electrode of the first reset transistor T65 and a first electrode of the second reset transistor T66 are both electrically connected to a reset signal line Vref, and a second electrode of the first reset transistor T65 is electrically connected to the gate of the driving transistor T60. A second electrode of the second reset transistor T66 is electrically connected to one electrode of the light-emitting element 12. The other electrode of the light-emitting element 12 is electrically connected to a second power supply voltage terminal PVEE. A first electrode plate of the storage capacitor Cst is electrically connected to the first power supply voltage terminal PVDD, and a second electrode plate of the storage capacitor Cst is electrically connected to the gate of the driving transistor T60.

It can be understood that, in the embodiments of the present disclosure, the first electrode of each of the aforementioned transistors may be one of a source and a drain, and the second electrode of each of the transistors may be the other of the source and the drain.

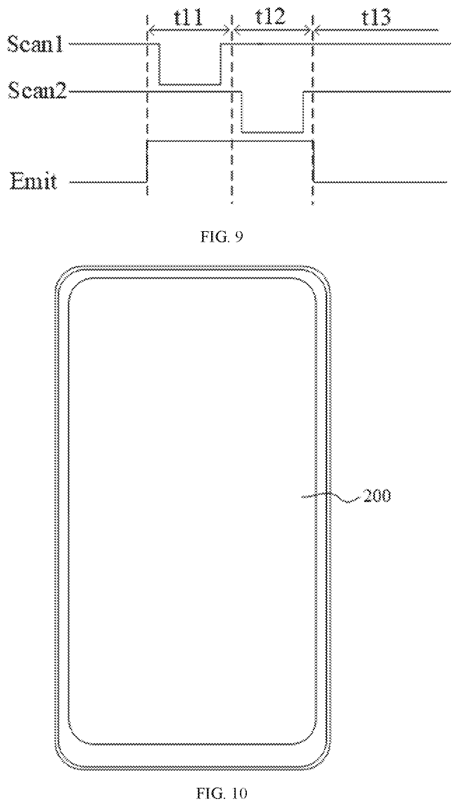

When the display panel is in operation, with reference to FIG. 8 and FIG. 9, where FIG. 9 is a schematic diagram of an operating timing of a subpixel according to an embodiment of the present disclosure, and during an initialization period t11, a first scan driving signal provided by the first scan line Scan1 is at a low level, a second scan driving signal provided by the second scan line Scan2 and a light-emitting control signal provided by the light-emitting control signal line Emit are respectively at a high level, a reset signal provided by the reset signal line Vref resets, via the turned-on first reset transistor T65, a voltage of the gate of the driving transistor T60, and resets, via the turned-on second reset transistor T66, the light-emitting element 12.

During a charging period t12, the second scan driving signal provided by the second scan line Scan2 is at a low level, the first scan driving signal provided by the first scan line Scan1 and the light-emitting control signal provided by the light-emitting control signal line Emit are respectively at a high level, and a data signal provided by the data line Vdata is written, via the turned-on data writing transistor T63, the driving transistor T60, and the threshold compensation transistor T64, to the gate of the driving transistor T60.

During a light-emitting period t13, the light-emitting control signal provided by the light-emitting control signal line Emit is at a low level, and the first scan driving signal provided by the first scan line Scan1 and the second scan driving signal provided by the second scan line Scan2 are respectively at a high level. The first light-emitting control transistor T61, the driving transistor T60, and the second light-emitting control transistor T62 are turned on, generating a driving current flowing from the first power supply voltage terminal PVDD to the second power supply voltage terminal PVEE, and the light-emitting element 12 emits light under the action of the driving current.

Based on the same inventive concept, an embodiment of the present disclosure further provides a display device, as shown in FIG. 10, which is a structural schematic diagram of a display device according to an embodiment of the present disclosure, the display device includes the aforementioned display panel 200, and the structure of the display panel 200 has been described in detail in the above embodiments, which will not be repeated here. Of course, the display device shown in FIG. 10 is merely illustrative, and the display device may be any electronic device having a display function, such as a mobile phone, a tablet computer, a laptop, or a television.

In the display device according to embodiments of the present disclosure, by configuring the shift register unit in the display panel to include the input module, the first inverter, the second inverter, the first cascade output module, and the second cascade output module, the output signal of the output terminal of the shift register unit can be shifted relative to the signal input to the first input terminal, thereby achieving the shifting function of the shift register unit.

Moreover, in the embodiments of the present disclosure, by providing the first inverter and the second inverter, the potential stability of the first node and the second node can be improved, the potential of the first node or the second node is prevented from being in a floating state, and the stability of the signal written into the internal node of the shift register unit can be improved. In addition, with this configuration, there is no need to provide a capacitor for stabilizing the potential of the first node or the second node in the shift register unit, and while ensuring signal stability, the circuit structure of the shift register unit can be simplified.

Based on the same inventive concept, an embodiment of the present disclosure further provides a driving method of a display panel. As shown in FIG. 1, the display panel includes a shift register circuit 2, and the shift register circuit 2 includes a plurality of cascaded shift register units 20.

As shown in FIG. 2, the shift register unit 20 includes: an input module 201, which is electrically connected to the first input terminal in1 and the first node P in response to the signal output by the clock signal terminal CK; and is electrically connected to the second input terminal in2 and the second node Q in response to the signal output by the clock signal terminal CK; a first inverter inv1 and a second inverter inv2, where the input terminal of the first inverter inv1 is electrically connected to the first node P, and the output terminal of the first inverter inv1 is electrically connected to the second node Q; the input terminal of the second inverter inv2 is electrically connected to the second node Q, and the output terminal of the second inverter inv2 is electrically connected to the first node P; a first cascade output module 2021, which is electrically connected to the first fixed potential signal terminal V1 and the first cascade output terminal next1 in response to the signal of the first node P; and a second cascade output module 2022, which is electrically connected to the second fixed potential signal terminal V2 and the second cascade output terminal next2 in response to the signal of the second node Q. The output terminal of the shift register unit 20 is electrically connected to the first node P.

With reference to FIG. 2 and FIG. 3, an operating cycle of the shift register unit 20 includes a first phase A1 and a second phase A2.

In the first phase A1, the input module 201, in response to the signal output by the clock signal terminal CK, provides an enable level to the first node P, where the enable level is used to control the first cascade output module 2021 to be turned on; the input module 201, in response to the signal output by the clock signal terminal CK, provides a disable level to the second node Q, where the disable level is used to control the second cascade output module 2022 to be turned off; the first cascade output module 2021, in response to the signal of the first node P, provides a disable level to the first cascade output terminal next1; and the second cascade output module 2022, in response to the signal of the second node Q, stops providing a disable level to the second cascade output terminal next2.

In the second phase A2, the input module 201, in response to the signal output by the clock signal terminal CK, provides a disable level to the first node P; the input module 201, in response to the signal output by the clock signal terminal CK, provides an enable level to the second node Q; the first cascade output module 2021, in response to the signal of the first node P, stops providing a disable level to the first cascade output terminal next1; and the second cascade output module 2022, in response to the signal of the second node Q, provides a disable level to the second cascade output terminal next2.

Exemplarily, as shown in FIG. 3, in the first phase A1, the second cascade output terminal next2 may output an enable level; in the second phase A2, the first cascade output terminal next1 may output an enable level.

Optionally, the enable levels of the first cascaded output terminal next1 and the second cascaded output terminal next2 may be obtained through feedback from the next-stage shift register unit 20 electrically connected to the current-stage shift register unit 20.

Taking, as an example, the i-th-stage shift register unit 20_i and the (i+1)-th-stage shift register unit 20_i+1 that are cascaded with each other as shown in FIG. 5, where the input module 201 of the i-th-stage shift register unit 20_i is electrically connected to a first clock signal terminal CK1, and the input module 201 of the (i+1)-th-stage shift register unit 20_i+1 is electrically connected to a second clock signal terminal CK2. With reference to FIG. 3, when the first cascade output terminal next1 of the i-th-stage shift register unit 20_i outputs a high level, the high level may be written into the second input terminal in2 of the (i+1)-th-stage shift register unit 20. When the second clock signal terminal CK2 provides an enable level, the input module 201 of the (i+1)-th-stage shift register unit 20 is turned on, and therefore, the high level at the second input terminal in2 of the (i+1)-th-stage shift register unit 20_i+1 may be written into the second node Q of the (i+1)-th-stage shift register unit 20, and after passing through the second inverter inv2, the potential of the first node P of the (i+1)-th-stage shift register unit 20 may be pulled low. Since the first node P and the first input terminal in1 are electrically connected through the first input transistor T1, the low-level signal of the first node P may be written into the first input terminal in1 and further be written into the second cascade output terminal next2 of the (i+1)-th-stage shift register unit 20.

Similarly, when the second cascade output terminal next2 of the i-th-stage shift register unit 20_i outputs a high level, the high level may be written into the first input terminal in1 of the (i+1)-th-stage shift register unit 20_i+1. When the second clock signal terminal CK2 provides an enable level, the input module 201 of the (i+1)-th-stage shift register unit 20_i+1 is turned on, and therefore, the high level at the first input terminal in1 of the (i+1)-th-stage shift register unit 20_i+1 may be written into the first node P of the (i+1)-th-stage shift register unit 20_i+1, and after passing through the first inverter inv1, the potential of the second node Q of the (i+1)-th-stage shift register unit 20_i+1 may be pulled low. Since the second node Q and the second input terminal in2 are electrically connected through the second input transistor T2, the low-level signal of the second node Q may be written into the second input terminal in2 and further be written into the first cascade output terminal next1 of the i-th-stage shift register unit 20_i.

Exemplarily, as shown in FIG. 3, the first phase A1 includes a first sub-phase A11 and a second sub-phase A12.

In the first sub-phase A11, an enable level is provided to the first input terminal in1_i of the i-th-stage shift register unit 20, a disable level is provided to the second input terminal in2_i of the i-th-stage shift register unit 20, an enable level is provided to the first clock signal terminal CK1 electrically connected to the i-th-stage shift register unit 20, and a disable level is provided to the second clock signal terminal CK2 electrically connected to the (i+1)-th-stage shift register unit 20. During this process, the input module 201 of the i-th-stage shift register unit 20 is turned on, and the input module 201 of the (i+1)-th-stage shift register unit 20 is turned off. The first node P_i of the i-th-stage shift register unit 20 is pulled low by its first input terminal in1_i, and the second node Q_i of the i-th-stage shift register unit 20 is pulled high by its second input terminal in2_i. Since the first node P_i of the i-th-stage shift register unit 20 is at a low level, the first cascade output terminal next1_i of the i-th-stage shift register unit 20 is pulled high by the first fixed potential signal terminal V1.

As shown in FIG. 3, in a second sub-phase A12, a disable level is provided to the first input terminal in1_i of the i-th-stage shift register unit 20, an enable level is provided to the second input terminal in2_i of the i-th-stage shift register unit 20, a disable level is provided to the first clock signal terminal CK1 electrically connected to the i-th-stage shift register unit 20, and an enable level is provided to the second clock signal terminal CK2 electrically connected to the (i+1)-th-stage shift register unit 20. During this process, the input module 201 of the i-th-stage shift register unit 20 is turned off, and the input module 201 of the (i+1)-th-stage shift register unit 20 is turned on. The first node P_i and the second node Q_i of the i-th-stage shift register unit 20 respectively maintain the low level and the high level of the first phase A1 under the action of the latch formed by the first inverter inv1 and the second inverter inv2. Therefore, the first cascade output terminal next1_i of the i-th-stage shift register unit 20 continues outputting the high level. Correspondingly, the second input terminal in2_i+1 of the (i+1)-th-stage shift register unit 20 is pulled high, the second node Q_i+1 thereof is pulled high, and the first node P_i+1 thereof is pulled low. Since the input module 201 of the (i+1)-th-stage shift register unit 20 is turned on under the control of the second clock signal terminal CK2, the first input terminal in1_i+1 of the (i+1)-th-stage shift register unit 20, which is electrically connected to the first node P_i+1 through the input module 201, is also pulled low. Moreover, since the second cascade output terminal next2_i of the i-th-stage shift register unit 20 is electrically connected to the first input terminal in1_i+1 of the (i+1)-th-stage shift register unit 20, the second cascade output terminal next2_i of the i-th-stage shift register unit 20 is fed back to a low level in the second phase A2.

Exemplarily, as shown in FIG. 3, the second phase A2 includes a third sub-phase A21 and a fourth sub-phase A22.

In the third sub-phase A21, a disable level is provided to the first input terminal in1_i of the i-th-stage shift register unit 20, an enable level is provided to the second input terminal in2_i of the i-th-stage shift register unit 20, an enable level is provided to the first clock signal terminal CK1 electrically connected to the i-th-stage shift register unit 20, and a disable level is provided to the second clock signal terminal CK2 electrically connected to the (i+1)-th-stage shift register unit 20. During this process, the input module 201 of the i-th-stage shift register unit 20 is turned on, and the input module 201 of the (i+1)-th-stage shift register unit 20 is turned off. The first node P_i of the i-th-stage shift register unit 20 is pulled high by its first input terminal in1_i, and the second node Q_i of the i-th-stage shift register unit 20 is pulled low by its second input terminal in2_i. Since the second node Q_i of the i-th-stage shift register unit 20 is at a low level, the second cascade output terminal next2_i of the i-th-stage shift register unit 20 is pulled high by the second fixed potential signal terminal V2. Since the first input terminal in1_i+1 of the (i+1)-th-stage shift register unit 20 is electrically connected to the second cascade output terminal next2_i of the i-th-stage shift register unit 20, when the second cascade output terminal next2_i of the i-th-stage shift register unit 20 is pulled high, the first input terminal in1_i+1 of the (i+1)-th-stage shift register unit 20 is also pulled high. Since the first node P_i of the i-th-stage shift register unit 20 is at a high level, the first cascade output terminal next1_i of the i-th-stage shift register unit 20 stops outputting the high level.

When the second cascade output terminal next2_i of the i-th-stage shift register unit 20 is pulled high, correspondingly, the first input terminal in1_i+1 of the (i+1)-th-stage shift register unit is written high; when the second clock signal terminal CK2 connected to the (i+1)-th-stage shift register unit 20 is at an enable level, the first node P_i+1 of the (i+1)-th-stage shift register unit is pulled high, the second node Q_i+1 thereof is pulled low, and the second input terminal in2_i+2 thereof is pulled low, thereby pulling low the first cascade output terminal next1_i of the i-th-stage shift register unit 20.

In the fourth sub-phase A22, a disable level is provided to the first input terminal in1_i of the i-th-stage shift register unit 20, an enable level is provided to the second input terminal in2_i of the i-th-stage shift register unit 20, a disable level is provided to the first clock signal terminal CK1 electrically connected to the i-th-stage shift register unit 20, and an enable level is provided to the second clock signal terminal CK2 electrically connected to the (i+1)-th-stage shift register unit 20. During this process, the input module 201 of the i-th-stage shift register unit 20 is turned off, and the input module 201 of the (i+1)-th-stage shift register unit 20 is turned on. The first node P and the second node Q of the i-th-stage shift register unit 20 respectively maintain the low level and the high level of the third sub-phase A21 under the action of the latch formed by the first inverter inv1 and the second inverter inv2, and therefore, the first cascade output terminal next1_i of the i-th-stage shift register unit 20 continues outputting the high level. The second input terminal in2_i+1 of the (i+1)-th-stage shift register unit is pulled high under the action of the first cascade output terminal next1_i of the shift register unit of the i-th stage, and therefore, the second node Q_i+1 of the (i+1)-th-stage shift register unit is pulled high, and correspondingly, the first node P_i+1 thereof is pulled low. Since the input module 201 of the (i+1)-th-stage shift register unit 20 is turned on in the fourth sub-phase A22, the first input terminal in1_i+1 of the (i+1)-th-stage shift register unit 20 is pulled low. Correspondingly, the second cascade output terminal next2_i of the i-th-stage shift register unit 20 is also pulled low.

Exemplarily, within one frame period, the number of the third sub-phase A21 and the fourth sub-phase A22 is not limited. FIG. 3 illustrates, as an example, a frame period including a plurality of third sub-phases A21 and a plurality of fourth sub-phases A22.

The above description just illustrates preferred embodiments of the present disclosure and is not intended to limit the present disclosure, and any modifications, equivalent substitutions, improvements and the like made within the spirit and principle of the present disclosure should be included within the protection scope of the present disclosure.

1. A display panel, comprising a plurality of subpixels and a shift register circuit, wherein the shift register circuit comprises a plurality of cascaded shift register units electrically connected to the plurality of subpixels,
wherein at least one of the plurality of shift register units comprises:
an input module, wherein the input module, in response to a signal output by a clock signal terminal, is electrically connected to a first input terminal and a first node, and is electrically connected to a second input terminal and a second node;
a first inverter and a second inverter, wherein an input terminal of the first inverter is electrically connected to the first node, and an output terminal of the first inverter is electrically connected to the second node; and an input terminal of the second inverter is electrically connected to the second node, and an output terminal of the second inverter is electrically connected to the first node;
a first cascade output module electrically connected to a first fixed potential signal terminal and a first cascade output terminal in response to a signal of the first node; and
a second cascade output module electrically connected to a second fixed potential signal terminal and a second cascade output terminal in response to a signal of the second node,
wherein an output terminal of the at least one shift register unit is electrically connected to the first node.

2. The display panel according to claim 1, wherein a signal input to the first fixed potential signal terminal has a same type as a signal of the second fixed potential signal terminal.

3. The display panel according to claim 1, wherein the first fixed potential signal terminal is electrically connected to the second fixed potential signal terminal.

4. The display panel according to claim 1, wherein signals input to the first input terminal and the second input terminal are inverse to each other.

5. The display panel according to claim 1, wherein a signal output by the clock signal terminal comprises a plurality of active pulses;
a rising edge of a signal input to the first input terminal and a falling edge of a signal input to the second input terminal are both located between two adjacent ones of the plurality of active pulses of the signal output by the clock signal terminal; and
a falling edge of the signal input to the first input terminal and a rising edge of the signal input to the second input terminal are both located between another two adjacent ones of the plurality of active pulses of the signal output by the clock signal terminal.

6. The display panel according to claim 1, wherein the clock signal terminal comprises a first clock signal terminal and a second clock signal terminal;
in two adjacent stages of shift register units, the input module of a one-stage shift register unit is responsive to a signal output by the first clock signal terminal, and the input module of—another stage shift register unit is responsive to a signal output by the second clock signal terminal; and
in two adjacent stages of shift register units, the second cascade output terminal of a previous-stage shift register unit is electrically connected to the first input terminal of a next-stage shift register unit, and the first cascade output terminal of the previous-stage shift register unit is electrically connected to the second input terminal of the next-stage shift register unit.

7. The display panel according to claim 6, wherein the signal output by the second clock signal terminal is a disable level in response to the signal output by the first clock signal terminal being an enable level; and
the signal output by the first clock signal terminal is a disable level in response to the signal output by the second clock signal terminal being the enable level.

8. The display panel according to claim 1, wherein the input module comprises a first input transistor and a second input transistor,
wherein a first electrode of the first input transistor is electrically connected to the first input terminal, and a second electrode of the first input transistor is electrically connected to the first node;
a first electrode of the second input transistor is electrically connected to the second input terminal, and a second electrode of the second input transistor is electrically connected to the second node;
a gate of the first input transistor and a gate of the second input transistor are electrically connected to the clock signal terminal; and
the first input transistor and the second input transistor have a same channel type.

9. The display panel according to claim 1, wherein the first cascade output module comprises a first output transistor, and the second cascade output module comprises a second output transistor,
wherein a first electrode of the first output transistor is electrically connected to the first fixed potential signal terminal, a second electrode of the first output transistor is electrically connected to the first cascade output terminal, and a gate of the first output transistor is electrically connected to the first node;
a first electrode of the second output transistor is electrically connected to the second fixed potential signal terminal, a second electrode of the second output transistor is electrically connected to the second cascade output terminal, and a gate of the second output transistor is electrically connected to the second node; and
the first output transistor and the second output transistor have a same channel type.

10. The display panel according to claim 9, wherein the first output transistor and the second output transistor are both P-type transistors.

11. The display panel according to claim 1, wherein a signal output by the first cascade output terminal and a signal output by the second cascade output terminal have opposite phases.

12. The display panel according to claim 1, wherein the first inverter comprises a first transistor and a second transistor having different channel types, wherein a first electrode of the first transistor is electrically connected to a first potential signal terminal, a second electrode of the first transistor is electrically connected to the second node, and a gate of the first transistor is electrically connected to the first node; and a first electrode of the second transistor is electrically connected to a second potential signal terminal, a second electrode of the second transistor is electrically connected to the second node, and a gate of the second transistor is electrically connected to the first node; and
the second inverter comprises a third transistor and a fourth transistor having different channel types, wherein a first electrode of the third transistor is electrically connected to the first potential signal terminal, a second electrode of the third transistor is electrically connected to the first node, and a gate of the third transistor is electrically connected to the second node;
and a first electrode of the fourth transistor is electrically connected to the second potential signal terminal, a second electrode of the fourth transistor is electrically connected to the first node, and a gate of the fourth transistor is electrically connected to the second node.

13. The display panel according to claim 1, wherein the at least one shift register unit further comprises a third inverter,
wherein an input terminal of the third inverter is electrically connected to the second node, and an output terminal of the third inverter is electrically connected to the output terminal of the at least one shift register unit.

14. The display panel according to claim 1, wherein the shift register circuit further comprises a starting signal line and a fourth inverter,
wherein in a first-stage shift register unit, one of the first input terminal and the second input terminal is electrically connected to the starting signal line and an input terminal of the fourth inverter, and another of the first input terminal and the second input terminal is electrically connected to an output terminal of the fourth inverter.

15. The display panel according to claim 1, wherein at least one of the plurality of subpixels comprises a pixel driving circuit, the pixel driving circuit comprises a light-emitting control module, and the shift register circuit is electrically connected to the light-emitting control module.

16. A display device, comprising a display panel, wherein the display panel comprises a plurality of subpixels and a shift register circuit, and the shift register circuit comprises a plurality of cascaded shift register units electrically connected to the plurality of subpixels,
wherein at least one of the plurality of shift register units comprises:
an input module, wherein the input module, in response to a signal output by a clock signal terminal, is electrically connected to a first input terminal and a first node, and is electrically connected to a second input terminal and a second node;
a first inverter and a second inverter, wherein an input terminal of the first inverter is electrically connected to the first node, and an output terminal of the first inverter is electrically connected to the second node; and an input terminal of the second inverter is electrically connected to the second node, and an output terminal of the second inverter is electrically connected to the first node;
a first cascade output module electrically connected to a first fixed potential signal terminal and a first cascade output terminal in response to a signal of the first node; and
a second cascade output module electrically connected to a second fixed potential signal terminal and a second cascade output terminal in response to a signal of the second node,
wherein an output terminal of the at least one shift register unit is electrically connected to the first node.

17. The display device according to claim 16, wherein a signal input to the first fixed potential signal terminal has a same type as a signal of the second fixed potential signal terminal.

18. The display device according to claim 16, wherein the first fixed potential signal terminal is electrically connected to the second fixed potential signal terminal.

19. The display device according to claim 16, wherein signals input to the first input terminal and the second input terminal are inverse to each other.

20. A driving method of a display panel, wherein the display panel comprises a shift register circuit, and the shift register circuit comprises a plurality of cascaded shift register units,
wherein at least one of the plurality of shift register units comprises:
an input module, wherein the input module is electrically connected to a first input terminal and a first node in response to a signal output by a clock signal terminal, and is electrically connected to a second input terminal and a second node in response to the signal output by the clock signal terminal;
a first inverter and a second inverter, wherein an input terminal of the first inverter is electrically connected to the first node, and an output terminal of the first inverter is electrically connected to the second node; and an input terminal of the second inverter is electrically connected to the second node, and an output terminal of the second inverter is electrically connected to the first node;
a first cascade output module electrically connected to a first fixed potential signal terminal and a first cascade output terminal in response to a signal of the first node; and
a second cascade output module electrically connected to a second fixed potential signal terminal and a second cascade output terminal in response to a signal of the second node,
wherein an output terminal of the at least one shift register unit is electrically connected to the first node;
wherein an operating cycle of the at least one shift register unit comprises a first phase and a second phase, and the driving method comprises:
in the first phase, providing, by the input module, an enable level to the first node and a disable level to the second node in response to the signal output by the clock signal terminal, wherein the enable level is configured to control the first cascade output module to be turned on, and the disable level is configured to control the second cascade output module to be turned off; providing, by the first cascade output module, the disable level to the first cascade output terminal in response to the signal of the first node; and providing, by the second cascade output module, the enable level to the second cascade output terminal in response to the signal of the second node; and
in the second phase, providing, by the input module, the disable level to the first node and the enable level to the second node in response to the signal output by the clock signal terminal;
providing, by the first cascade output module, the enable level to the first cascade output terminal in response to the signal of the first node; and providing, by the second cascade output module, the disable level to the second cascade output terminal in response to the signal of the second node.
